(19) United States
(12) Patent Application Publication
(10) Pub. No.: US 2010/0155941 A1
(43) Pub. Date: Jun. 24, 2010

(54) SEMICONDUCTOR DEVICE

(75) Inventors: Hirohisa Matsuki, Kawasaki (JP); Kazuyuki Imamura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Yokohama-shi (JP)

(21) Appl. No.: 12/690,469

(22) Filed: Jan. 20, 2010

Related U.S. Application Data
(63) Continuation of application No. PCT/JP2007/064601, filed on Jul. 25, 2007.

(51) Int. Cl. H01L 23/498

(52) U.S. Cl. 257/737; 257/E23.068

(57) ABSTRACT

A semiconductor device includes multiple electrode pads provided in an interconnection layer over a semiconductor substrate; an insulating layer provided on the interconnection layer so as to expose portions of the electrode pads; multiple conductive layers having their respective first ends connected to the exposed portions of the corresponding electrode pads so as to extend therefrom on the insulating layer; and multiple protruding electrodes provided at respective second ends of the conductive layers, wherein the conductive layers extend in a given direction relative to the electrode pads.

### CROSS-REFERENCE TO RELATED APPLICATION

This application is a continuation application filed under 35 U.S.C. 111(a) claiming benefit under 35 U.S.C. 120 and 365(c) of PCT International Application No. PCT/JP2007/064601, filed on Jul. 25, 2007, the entire contents of which are incorporated herein by reference.

### FIELD

A certain aspect of the embodiments discussed herein is related to a semiconductor device.

### BACKGROUND

In these years, as electronic apparatuses have become more sophisticated and faster in operating speed, semiconductor devices to be mounted on such electronic apparatuses also have been desired to be more sophisticated, more integrated, and smaller in size. Therefore, so-called flip chip mounting has been employed as a method for mounting a semiconductor device (element) on a support board such as a wiring board, by which the semiconductor device is mounted face-down on the wiring board through external connection protruding electrodes called solder bumps.

FIG. 1 illustrates a surface having solder bumps provided thereon of such a semiconductor device (element) to which flip chip mounting is applied. FIG. 2 illustrates a cross section of the semiconductor device of FIG. 1 taken along broken line A-A.

Referring to FIG. 1 and FIG. 2, in a semiconductor device (element) 30, multiple functional elements (not graphically illustrated) including active elements such as a transistor and passive elements such as a capacitive element are formed on one of the principal surfaces of a semiconductor substrate 1 of silicon (Si) through application of a so-called wafer process. These functional elements including active elements and passive elements are interconnected through a multi-layer interconnection layer 3, formed over the principal surface of the semiconductor substrate 1 with interposition of an insulating layer 2 such as a silicon oxide (SiO₂) layer, so that an electronic circuit is formed.

This multi-layer interconnection layer 3 includes multiple interconnection layers 4 and multiple interlayer insulating layers 5. The interconnection layers 4 are formed of a material such as aluminum (Al) or copper (Cu), and are stacked alternately with two or more of the interlayer insulating layers 5. The functional elements formed between the upper and lower interconnection layers 4 and in the semiconductor substrate 1 are suitably connected through interlayer connection parts 6.

A low dielectric constant material (a so-called low-k material) such as organic resin, silicon oxycarbide (SiOC), or fluorine (F) doped silicon glass (FSG) is used as the material of the interlayer insulating layers 5 so as to reduce the capacitance between interconnects and increase the rate of electrical signal transmission.

Multiple aluminum (Al) electrode pads 7 are selectively provided at the top of the multi-layer interconnection layer 3, and are suitably connected to the interconnection layers 4 of the multi-layer interconnection layer 3.

An inorganic insulating layer 8, which is formed of, for example, silicon nitride (SiN) or silicon oxide (SiO₂) and also referred to as a passivation layer, is selectively provided on the multi-layer interconnection layer 3. The inorganic insulating layer 8 selectively includes openings so as to expose the center parts of the electrode pads 7.

Further, in order to protect the surface of the semiconductor device 30, an organic insulating layer 9 is selectively provided so as to cover the upper surface of the inorganic insulating layer 8 and the end faces of the inorganic insulating layer 8 on the electrode pads 7.

The material of the organic insulating layer 9 is selected from organic insulating materials such as polyimide, benzocyclobutene, phenolic resin, and polybenzoxazole.

A first under-bump metallization (UBM) layer 10 of titanium (Ti) or chromium (Cr) and a second UBM layer 11 of nickel (Ni) or copper (Cu) are stacked on the portions of the electrode pads 7 which portions are not covered with the inorganic insulating layer 8 or the organic insulating layer 9. The first UBM layer 10 and the second UBM layer 11 are provided in the openings of the organic insulating layer 9 so as to cover its end faces and their periphery.

Substantially spherical external connection protruding electrodes 12 are provided on the second UBM layer 11. The external connection protruding electrodes 12 are formed of lead-free (Pb-free) solder such as tin-silver (Sn—Ag) solder or tin-silver-copper (Sn—Ag—Cu) solder, and are also referred to as solder bumps.

The semiconductor device 30 having the above-described structure is formed through the following process.

That is, the inorganic insulating layer 8 and the organic insulating layer 9 are provided on the multi-layer interconnection layer 3 so as to selectively expose the electrode pads 7 selectively provided at the top of the multi-layer interconnection layer 3. The inorganic insulating layer 8 and the organic insulating layer 9 are deposited by so-called vapor deposition. So-called photoetching may be applied to the selective formation of openings in the inorganic insulating layer 8 and the organic insulating layer 9.

Next, the first UBM layer 10 is formed so as to extend on the organic insulating layer 9 and the exposed portions of the electrode pads 7. The first UBM layer 10 may be deposited by so-called sputtering.

Next, a photoresist layer is formed on the first UBM layer 10. The photoresist layer is exposed to light, developed, and hardened so as to form openings in the photoresist layer, which openings correspond to where the external connection protruding electrodes 12 are to be formed over the corresponding electrode pads 7.

Next, electroplating is performed to form the second UBM layer 11 on the first UBM layer 10 exposed in the openings in the photoresist layer. Then, an external connection electrode layer is formed on the second UBM layer 11. At this point, the external connection electrode layer is formed to extend on the photoresist layer.

Thereafter, the photoresist layer is removed. Further, unnecessary portions of the first UBM layer 10 are removed using the external connection electrode layer as an etching mask.

Next, the external connection electrode layer is caused to melt by reflow heating so as to be shaped into substantial spheres. As a result, the semiconductor device 30 is formed, where the substantially spherical external connection protruding electrodes 12 are formed on the second UBM layer 11 over the semiconductor substrate 1.

FIG. 3 illustrates the semiconductor device 30 flip-chip mounted on a wiring board 21. The semiconductor device 30 is mounted face-down on the wiring board 21. The wiring board 21 is formed of an organic built-up substrate formed of a glass epoxy material or a polyimide tape. Multiple electrode pads 22 are selectively provided on a first principal surface (upper surface) of the wiring board 21, which surface is covered with solder resist 23. The solder resist 23 selectively has openings so as to expose the center parts of the electrode pads 22.

The external connection protruding electrodes 12 of the semiconductor device 30 are connected to the corresponding electrode pads 22 provided on the wiring board 21. Further, the space between the semiconductor device 30 and the wiring board 21 is filled with a so-called underfill material 24. Multiple external connection protruding electrodes 25 formed of solder are provided on a second principal surface (lower surface) of the wiring board 21.

A semiconductor device 50 having the above-described structure is formed through the following process.

That is, the semiconductor device 30 is flip-chip mounted (mounted face-down) on the first principal surface (upper surface) of the wiring board 21.

Next, the external connection protruding electrodes 12 of the semiconductor device 30 and additional solder (a solder precoat) (not graphically illustrated) provided in advance on the electrode pads 22 of the wiring board 21 are caused to melt by reflow heating, so that the external connection protruding electrodes 12 of the semiconductor device 30 are connected (joined) to the corresponding electrode pads 22 on the wiring board 21.

Next, the space between the semiconductor device 30 and the wiring bard 21 is filled with the underfill material 24, and the underfill material 24 is then hardened.

Thereafter, solder balls are provided on the second principal surface (lower surface) of the wiring board 21 so as to form the external connection protruding electrodes 25 through a reflow heating process and a cooling process.

Thus, in order to prevent degradation of the electrical characteristics of a semiconductor device at the time of providing external connection terminals on a semiconductor substrate, a semiconductor device has been proposed that includes an internal interconnection layer connected to an electronic circuit formed in a semiconductor substrate; a via connected to the internal interconnection layer at any position on the semiconductor substrate and exposed on the surface of a protection layer formed on the semiconductor substrate; an interconnection layer formed on the protection layer and connected to the via; and an external connection terminal connected to the interconnection layer and having a predetermined height, wherein no electronic circuit is provided immediately below the via, and the diameter of the via is less than or equal to the width of the interconnection layer. (See, for example, Japanese Laid-open Patent Publication No. 2000-243876.)

Further, a semiconductor integrated circuit device has been proposed where a solder bump electrode containing tin (Sn) is provided on an under-bump conductor layer on an extension electrode of a semiconductor integrated circuit formed on a semiconductor substrate and the under-bump conductor layer is formed by providing a conductor layer containing palladium (Pd) on a conductor layer with an adhesion function provided on the extension electrode. (See, for example, Japanese Patent No. 3645391.)

### SUMMARY

According to an aspect of the invention, a semiconductor device includes a plurality of electrode pads provided in an interconnection layer over a semiconductor substrate; an insulating layer provided on the interconnection layer so as to expose portions of the electrode pads; a plurality of conductive layers having respective first ends thereof connected to the exposed portions of the corresponding electrode pads so as to extend therefrom on the insulating layer; and a plurality of protruding electrodes provided at respective second ends of the conductive layers, wherein the conductive layers extend in a given direction relative to the electrode pads.

The object and advantages of the invention will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWING(S)

FIG. 1 is a plan view of a conventional semiconductor device (element) illustrating its structure;

FIG. 2 is a cross-sectional view of the semiconductor device of FIG. 1 taken along line A-A;

FIG. 3 is a diagram illustrating the semiconductor device of FIG. 1 and FIG. 2 flip-chip mounted on a wiring board;

FIG. 4 is a plan view of a semiconductor device (element) applied to a semiconductor device according to a first embodiment;

FIG. 5A is a cross-sectional view of the semiconductor device (element) of FIG. 4 taken along broken line A-A according to the first embodiment;

FIG. 5B is an enlarged view of a circled portion of FIG. 5A according to the first embodiment;

FIG. 6 is a diagram illustrating a variation of the semiconductor device (element) illustrated in FIGS. 5A and 5B according to the first embodiment;

FIG. 7 is a diagram illustrating the semiconductor device of FIG. 4 and FIGS. 5A and 5B flip-chip mounted on a wiring board according to the first embodiment;

FIG. 8 is a plan view of a first variation of the form of the leading out and extension of the layered structure of a first under-bump metallization (UBM) layer and a second UBM layer in the semiconductor device (element) according to the first embodiment;

FIG. 9 is a plan view of a second variation of the form of the leading out and extension of the layered structure of a first under-bump metallization (UBM) layer and a second UBM layer in the semiconductor device (element) according to the first embodiment;

FIGS. 10A and 10B are diagrams illustrating a structure of a semiconductor device (element) applied to a semiconductor device according to a second embodiment; and

FIG. 11 is a flowchart for illustrating a method of manufacturing a semiconductor device according to the first embodiment.

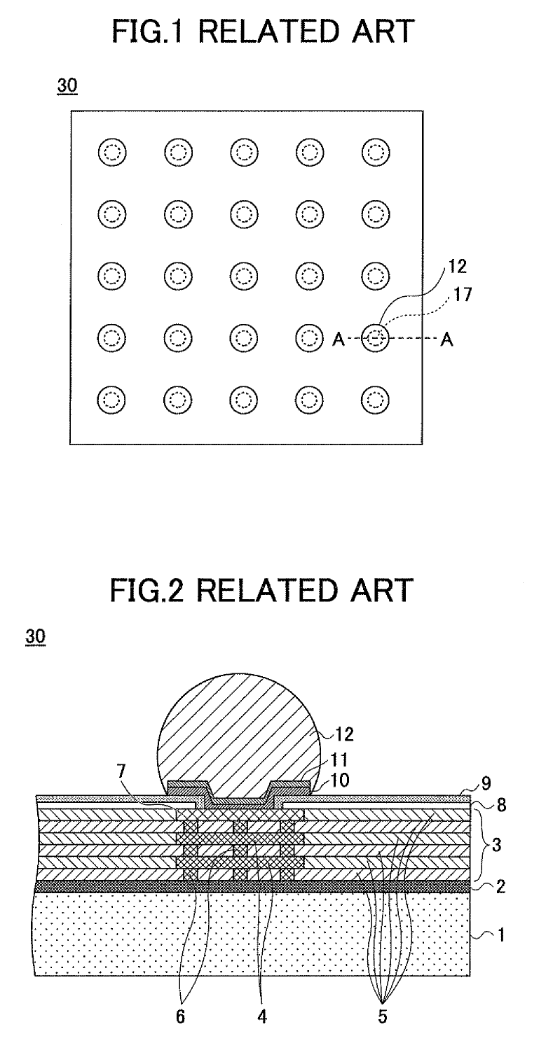

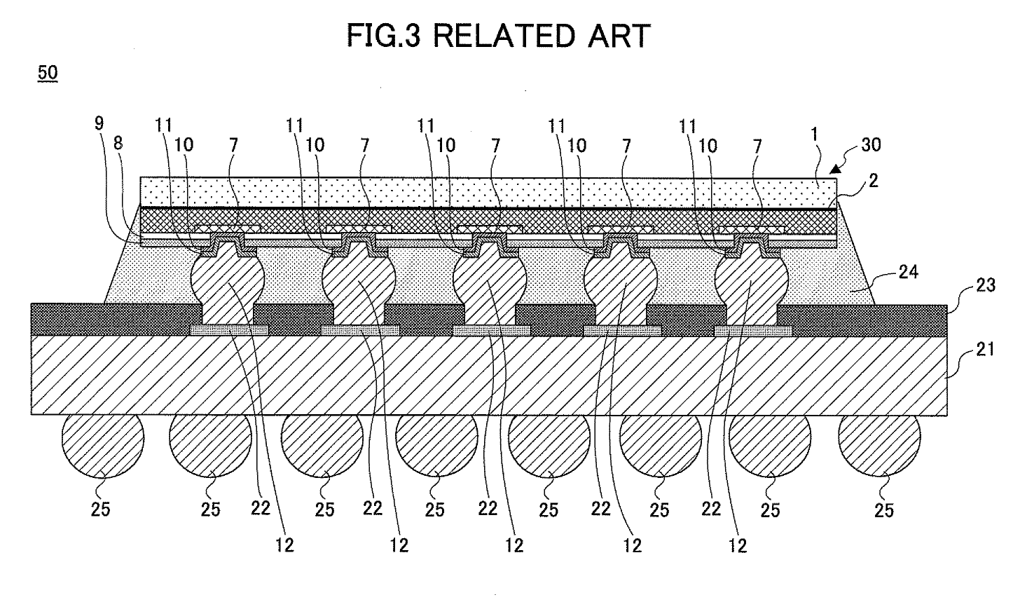

### DESCRIPTION OF EMBODIMENTS

As described above, according to the method of manufacturing a semiconductor device where the semiconductor device (element) 30 is flip-chip mounted on the wiring board 21 through the external connection protruding electrodes 12 provided on the surface of the semiconductor device 30, the external connection protruding electrodes 12 of the semiconductor device 30 and the electrode pads 22 on the wiring board 21 are connected by causing the external connection protruding electrodes 12 and the coating of additional solder (solder precoat) provided in advance on the electrode pads 22 of the wiring board 21 to melt in a reflow heating process. Thereafter, cooling is performed to solidify the external connection protruding electrodes 12.

The silicon (Si) substrate 1 of this semiconductor device 30 has a coefficient of thermal expansion of approximately 3 ppm/° C. to approximately 4 ppm/° C., while the wiring board 21 formed of an organic material has a coefficient of thermal expansion of approximately 10 ppm/° C. to approximately 17 ppm/° C. Thus, the wiring board 21 has a coefficient of thermal expansion greater than that of the semiconductor device 30.

Accordingly, cooling after the reflow heating process for heating the external connection protruding electrodes 12 generates a conspicuous strain or stress based on the difference between the coefficient of thermal expansion of the semiconductor device 30 and the coefficient of thermal expansion of the wiring board 21. That is, since the wiring board 21 has a coefficient of thermal expansion greater than that of the semiconductor device 30, such cooling causes stress to be exerted onto the semiconductor device 30 from the wiring board 21, which expands or contracts to a greater extent in response to a change in temperature.

This state occurs when the solder material (the external connection protruding electrodes 12 and additional solder) is solidified. Accordingly, the stress exerted onto the semiconductor device from the wiring board 21 is not absorbed by the solder (material).

Accordingly, the stress exerted from the wiring board 21 onto the external connection protruding electrodes 12 of the semiconductor device 30 is exerted onto the interlayer insulating layers 5 formed of a so-called low-k material in the multi-layer interconnection layer 3 through the second UBM layer 11, the first UBM layer 10, and the electrode pads 7.

As a result, interlayer separation occurs in the interconnection layers 4 stacked alternately with two or more of the interlayer insulating layers 5, thus causing electrical failure in the semiconductor device 50.

According to an aspect of the present invention, a semiconductor device is provided that, at the time of mounting a semiconductor element on a wiring board through the external connection protruding electrodes of the semiconductor element, may relieve stress exerted from the wiring board through the external connection protruding electrodes onto the multi-layer interconnection part of the semiconductor element including interlayer insulating layers formed of a low-k material, thereby preventing occurrence of interlayer separation in the interconnection layers.

Preferred embodiments of the present invention will be explained with reference to accompanying drawings.

### First Embodiment

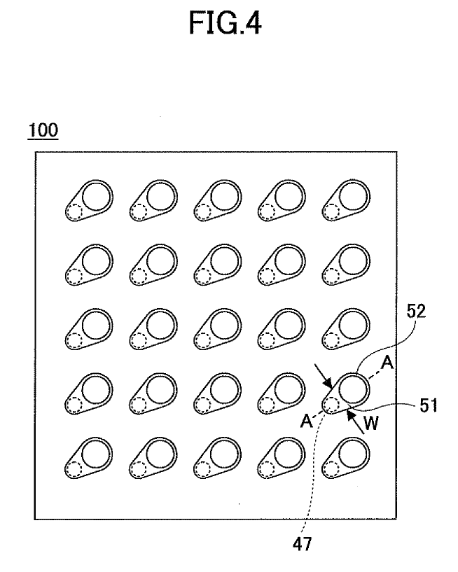

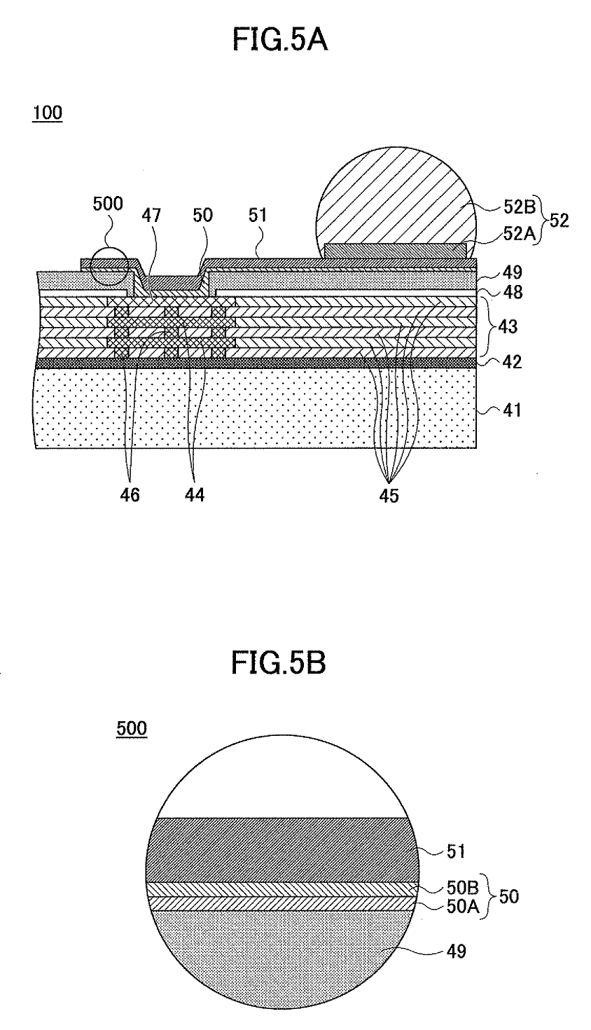

FIG. 4 illustrates a principal surface of a semiconductor device (element) according to a first embodiment. FIG. 5A illustrates a cross section of the semiconductor device of FIG. 4 taken along broken line A-A. FIG. 5B is an enlarged view of a circled portion 500 of FIG. 5A.

Referring to FIG. 4 and FIGS. 5A and 5B, in a semiconductor device (element) 100 according to the first embodiment, multiple functional elements (not graphically illustrated) including active elements such as a transistor and passive elements such as a capacitive element are provided on one of the principal surfaces of a semiconductor substrate 41 of silicon (Si) through application of a so-called wafer process.

These functional elements including active elements and passive elements are interconnected through a multi-layer interconnection layer 43, formed over the principal surface of the semiconductor substrate 41 with interposition of an insulating layer 42 such as a silicon oxide (SiO₂) layer, so that an electronic circuit is formed.

According to this configuration, as illustrated in FIG. 5A, the multi-layer interconnection layer 43 includes multiple interconnection layers 44 and multiple interlayer insulating layers 45. The interconnection layers 44 are formed of a material such as aluminum (Al) or copper (Cu), and are stacked alternately with two or more of the interlayer insulating layers 45. The functional elements formed between the upper and lower interconnection layers 44 and in the semiconductor substrate 41 are suitably connected through interlayer connection parts 46. That is, part of the interconnection layers 44 selectively penetrates through the insulating layer 42 to be connected to the functional elements formed in the semiconductor substrate 41.

The interlayer connection parts 46 are formed of a material such as aluminum (Al), copper (Cu), or tungsten (W).

A material having a relative dielectric constant lower than or equal to 5 (a so-called low-k material) such as organic resin, silicon oxycarbide (SiOC), or fluorine (F) doped silicon glass (FSG) is used as the material of the interlayer insulating layers 45 so as to reduce the capacitance between interconnects and increase the rate of electrical signal transmission.

Multiple aluminum (Al) electrode pads (electrode parts) 47 are provided at the top of the multi-layer interconnection layer 43, and are suitably connected to the interconnection layers 44 of the multi-layer interconnection layer 43. Referring to FIG. 4, the electrode pads 47 are provided in a grid-like manner, that is, at substantially equal intervals vertically and horizontally, like a so-called matrix on a principal surface of the semiconductor device 100.

Further, an inorganic insulating layer (film) 48, which is formed of, for example, silicon nitride (SiN) or silicon oxide (SiO₂), is selectively provided on the multi-layer interconnection layer 43 so as to have openings that expose the center parts of the electrode pads 47. The inorganic insulating layer 48 is also referred to as a passivation layer.

The openings of the inorganic insulating layer 48 on the electrode pads 47 are greater than or equal to 15 μm in diameter. Opening diameters smaller than 15 μm increases contact resistance so as to make it difficult to establish good electrical connection.

Further, in order to protect the surface of the semiconductor device 100, an organic insulating layer (film) 49 is provided so as to cover the upper surface of the inorganic insulating layer 48 and the end faces (internal side faces) of the inorganic insulating layer 48 on the electrode pads 47.

An insulating material having a Young's modulus of approximately 2 GPa to approximately 20 GPa is applied as the organic insulating layer 49. The insulating material is selected from, for example, polyimide, benzocyclobutene, phenolic resin, and polybenzoxazole. The organic insulating layer 49 is more than or equal to 5 μm in film thickness.

A first under-bump metallization (UBM) layer 50 and a second UBM layer 51 are stacked in layers on the exposed portions of the electrode pads 47, that is, the surfaces of the electrode pads 47 that are not covered with the inorganic insulating layer 48 or the organic insulating layer 49, to extend on the organic insulating layer 49. The layered structures of the first UBM layer 50 and the second UBM layer 51 gradually increase in width (indicated as W by double-headed arrows in FIG. 4) as they extend in a direction away from the exposed portions of the corresponding electrode pads 47.

As illustrated in FIG. 5B, the first UBM layer 50 includes a lower metallization layer 50A of titanium (Ti) or chromium (Cr) and an upper metallization layer 50B of copper (Cu) provided on the lower metallization layer 50A. These lower and upper metallization layers 50A and 50B are deposited by sputtering. The material of the lower metallization layer 50A is selected (determined) also in view of adhesion to the organic insulating material of the organic insulating layer 49.

On the other hand, copper (Cu) or nickel (Ni) is applied as the second UBM layer 51. The metallization layer of the second UBM layer 51 is deposited by plating. At this point, the upper metallization layer 50B of the first UBM layer 50 facilitates deposition of the second UBM layer 51. The second UBM layer 51 is more than or equal to 5 μm in thickness, and supports relaxation of stress at the time of thermal contraction.

Protruding electrodes for external connection (external connection protruding electrodes) 52 are selectively provided on the second UBM layer 51. The external connection protruding electrodes 52 include an underlayer 52A formed of nickel (Ni) or copper (Cu) and a low-melting metal layer 52B provided on the underlayer 52A.

The low-melting metal layer 52B is formed of an alloy whose melting point is lower than or equal to approximately 350° C., for example, so-called lead-free solder or solder that does not contain lead (Pb), such as tin-silver (Sn—Ag) solder or tin-silver-copper (Sn—Ag—Cu) solder. The low-melting metal layer 52B is also referred to as a solder bump. The area of contact of the low-melting metal layer 52B with the underlayer 52A is larger than the area of the electrode pad 47.

A metal coating of gold (Au), copper (Cu), nickel (Ni), or tin (Sn) may be provided or formed on the surfaces of the external connection protruding electrodes 52. The shape of the external connection protruding electrodes 52 is not limited to a substantial hemisphere as illustrated in FIG. 5A, and may be substantially cylindrical.

According to this configuration, as illustrated in FIG. 4, the layered structures of the first UBM layer 50 and the second UBM layer 51 connected to the corresponding electrode pads 47 are provided to extend in the same (uniform) direction with the same (uniform) length.

As a result, the external connection protruding electrodes 52 are provided at substantially equal intervals vertically and horizontally like a so-called matrix, at substantially the same intervals as the intervals at which the electrode pads 47 are provided, on the principal surface of the semiconductor device 100.

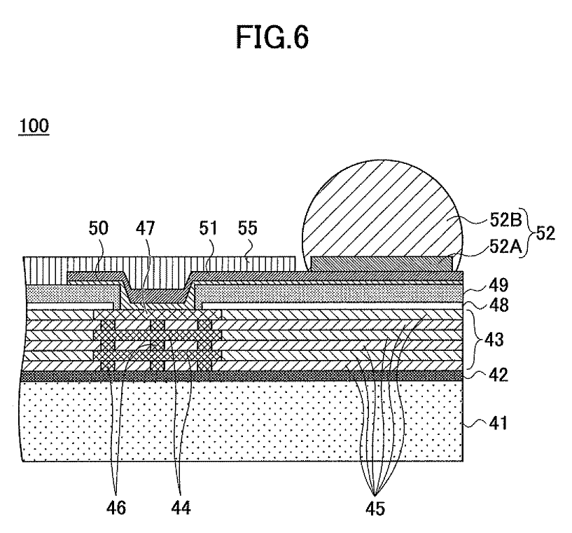

As illustrated in FIG. 6, the semiconductor device 100 may have an insulating material part 55 of organic matter covering the upper surface of the organic insulating layer 49 and the exposed portions of the upper surfaces of the layered structures of the first UBM layer 50 and the second UBM layer 51, which exposed portions are not covered with the external connection protruding electrodes 52.

Such covering with the insulating material part 55 makes it possible to prevent oxidation of the surface of the second UBM layer 51 and to protect the organic insulating layer 49.

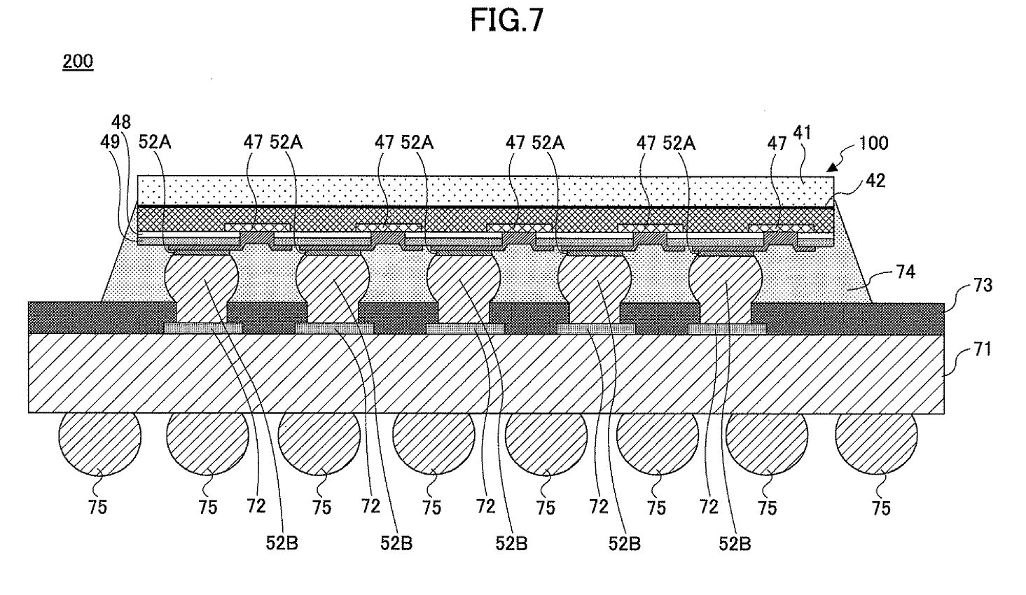

FIG. 7 illustrates a semiconductor device 200 having the semiconductor device (element) 100 configured as described above flip-chip mounted on (over) a wiring board 71.

The wiring board 71 is formed of an organic built-up substrate formed of a glass epoxy material or a polyimide tape. Multiple electrode pads 72 are selectively provided on a first principal surface (upper surface) of the wiring board 71. A solder resist 73 having openings so as to expose the center parts of the electrode pads 72 is selectively provided on the first principal surface of the wiring board 71.

The external connection protruding electrodes 52 of the semiconductor device 100 are connected to the corresponding electrode pads 72 provided on the wiring board 71. The space between the semiconductor device 100 and the wiring board 71 is filled with so-called underfill material 74. Further, multiple external connection protruding electrodes 75 formed of solder are provided on a second principal surface (lower surface) of the wiring board 71.

As described above, in the semiconductor device 100 according to the first embodiment, the first and second UBM layers 51 and 52 extend from the electrode pads 47 so as to have the external connection protruding electrodes 52 positioned and provided in regions offset sideward from the electrode pads 47. That is, the entire lower surfaces of the external connection protruding electrodes 52 are positioned over the organic insulating layer 49 with interposition of the second UBM layer 51 and the first UBM layer 50.

Accordingly, even if cooling after reflow heating at the time of mounting the semiconductor device 100 on the wiring board 71 causes a stress to be exerted onto the external connection protruding electrodes 52 of the semiconductor device 100 from the wiring board 71 based on the difference between the coefficients of thermal expansion of the semiconductor device 100 and the wiring board 71, the stress is prevented from directly affecting the electrode pads 47. The stress is dispersed (distributed) among the second UBM layer 51, the first UBM layer 50, and the organic insulating layer 49 to be relieved.

This prevents the stress exerted on the external connection protruding electrodes 52 of the semiconductor device 100 from working on the interlayer insulating layers 45 formed of a so-called low-k material in the multi-layer interconnection layer 43 through the electrode pads 47 at the time of mounting the semiconductor device 100 on the wiring board 71. Further, it is possible to prevent occurrence of interlayer separation in the interconnection layers 44 stacked alternately with two or more of the interlayer insulating layers 45 and thus to avoid occurrence of electrical failure in the semiconductor device 200.

The organic insulating layer 49, which has elasticity, contributes to distribution (reduction) of the stress exerted toward the second UBM layer (second metal part) 51 from the wiring board 71 through the external connection protruding electrodes 52 at the time of mounting the semiconductor device (element) 100 on the wiring board 71.

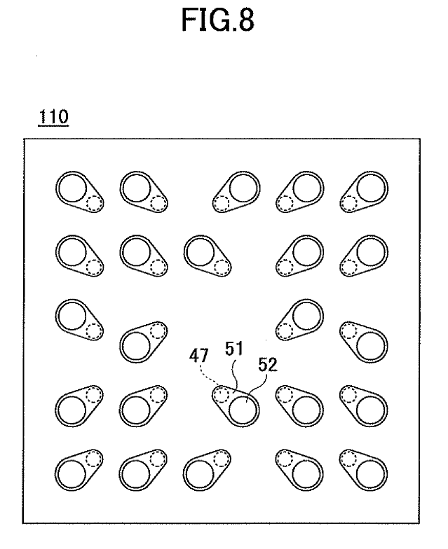

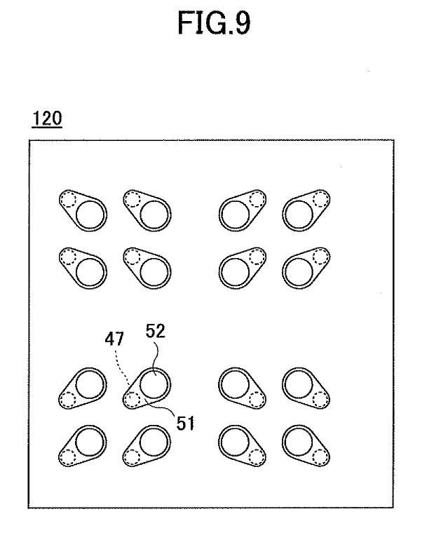

The direction in which the layered structures of the first UBM layer 50 and the second UBM layer 51 are led out and extend in the semiconductor device 100 is not limited to the one described in this embodiment, and may be selected from various options. That is, for example, the configuration illustrated in FIG. 8 or FIG. 9 may also be employed.

FIG. 8 illustrates a first variation of the form of the leading out and extension of the layered structure of the first UBM layer 50 (not graphically illustrated in FIG. 8) and the second UBM layer 51 in a semiconductor device (element) 110 according to the first embodiment.

The electrode pads 47 are provided in a grid-like manner, that is, at equal intervals vertically and horizontally, on a principal surface of the semiconductor device 110 except its center part. Here, the electrode pads 47 are divided into four groups with respect to their positions at which they are provided. The layered structures of the first UBM layer 50 and the second UBM layer 51 connected to the corresponding electrode pads 47 are grouped in correspondence to the groups of the electrode pads 47. The four groups of the layered structures are led out to extend toward the respective four corners (corner parts) of the semiconductor device 110.

This configuration makes it possible to have more latitude in arranging the external connection protruding electrodes 52 without the positions of the adjacent external connection protruding electrodes 52 overlapping each other, and to prevent formation of the external connection protruding electrodes 52 with directional bias in the vicinity of the end portions of the principal surface of the semiconductor device 110.

FIG. 9 illustrates a second variation of the form of the leading out and extension of the layered structure of the first UBM layer 50 (not graphically illustrated in FIG. 9) and the second UBM layer 51 in a semiconductor device (element) 120 according to the first embodiment.

The electrode pads 47 are provided in a grid-like manner, that is, at equal intervals vertically and horizontally, on a principal surface of the semiconductor device 120 as if to be distributed among the four corners (corner parts) of the principal surface.

The electrode pads 47 are divided into four groups with respect to their positions at which they are provided. The layered structures of the first UBM layer 50 and the second UBM layer 51 connected to the corresponding electrode pads 47 are grouped in correspondence to the groups of the electrode pads 47. The four groups of the layered structures are led out to extend toward the substantial center of the semiconductor device 120 (from the electrode pads 47 in a direction away from the respective four corners).

This configuration also makes it possible to have more latitude in arranging the external connection protruding electrodes 52 without the positions of the adjacent external connection protruding electrodes 52 overlapping each other, and to prevent formation of the external connection protruding electrodes 52 with directional bias in the vicinity of the end portions of the principal surface of the semiconductor device 120.

In general, in a wiring board on which a semiconductor device (element) is mounted, a greater stress is exerted on the four corners (corner parts) of the semiconductor device by expansion or contraction due to a change in temperature. Accordingly, it is possible to suppress or reduce the stress to be exerted on the electrode pads 47 by thus providing the layered structures of the first UBM layer 50 and the second UBM layer 51 and providing the external connection protruding electrodes 52 at positions offset toward the center of the semiconductor device 120 from the positions of the electrode pads 47.

### Second Embodiment

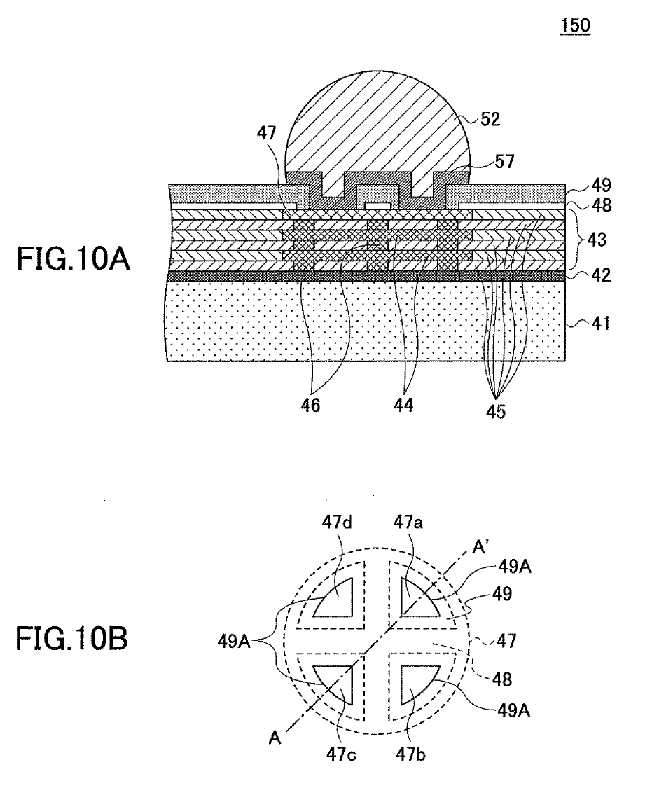

Next, a description is given, with reference to FIGS. 10A and 10B, of a semiconductor device (element) according to a second embodiment.

FIGS. 10A and 10B illustrate one of the external connection protruding electrodes 52 and an interconnection layer structure connected to the one of the external connection protruding electrodes 52 in a semiconductor device (element) 150 according to the second embodiment. FIG. 10A illustrates the one of the external connection protruding electrodes 52 and a cross-sectional view of the interconnection layer structure connected to the one of the external connection protruding electrodes 52. FIG. 10B illustrates a planar shape of an electrode pad part before the one of the external connection protruding electrodes 52 and an under-bump metallization (UBM) layer are provided on the electrode pad part. FIG. 10A corresponds to the cross section of FIG. 10B taken along line A-A′.

In FIGS. 10A and 10B, the elements or configurations corresponding to those of the semiconductor device 100 according to the first embodiment are referred to by the same reference numerals.

In the semiconductor device 150 according to the second embodiment, multiple functional elements (not graphically illustrated) including active elements such as a transistor and passive elements such as a capacitive element are provided on one of the principal surfaces of the semiconductor substrate 41 of silicon (Si) through application of a so-called wafer process. Further, the multi-layer interconnection layer 43 is formed over the principal surface of the semiconductor substrate 41 with interposition of the insulating layer 42 such as a silicon oxide (SiO₂) layer.

The multi-layer interconnection layer 43 includes the multiple interconnection layers 44 and the multiple interlayer insulating layers 45. The interconnection layers 44 are stacked alternately with two or more of the interlayer insulating layers 45. The upper and lower interconnection layers 44 are suitably connected through the interlayer connection parts 46.

The multiple aluminum (Al) electrode pads (electrode parts) 47 are provided at the top of the multi-layer interconnection layer 43, and are suitably connected to the interconnection layers 44 of the multi-layer interconnection layer 43. According to this embodiment as well, the electrode pads 47 are provided in a grid-like manner, that is, at substantially equal intervals vertically and horizontally, like a so-called matrix on a principal surface of the semiconductor device 150.

Further, the inorganic insulating layer 48, which is formed of, for example, silicon nitride (SiN) or silicon oxide (SiO₂) and has openings that selectively expose the surfaces of the electrode pads 47, and the organic insulating layer 49 of polyimide or the like are stacked and provided on the multi-layer interconnection layer 43.

According to one aspect of this embodiment, the insulating layers 48 and 49 are formed selectively on the electrode pads 47 so as to divide the surfaces of the electrode pads 47 into multiple regions and expose the divided regions. That is, the inorganic insulating layer 48 that selectively covers the surfaces of the electrode pads 47 and the organic insulating layer that covers the upper and side surfaces of the inorganic insulating layer 48 are provided on the electrode pads 47.

As a result, the organic insulating layer 49 covers the surface of the inorganic insulating layer 48 and selectively exposes the surfaces of the electrode pads 47.

According to this embodiment, as illustrated in FIG. 10B, the inorganic insulating layer 48 is provided like a crisscross on the surfaces of the electrode pads 47, and the organic insulating layer 49 is further provided to cover the inorganic insulating layer 48.

As a result, the surface of each of the electrode pads 47 is divided into four regions 47a, 47b, 47c, and 47d, which are exposed at corresponding sector-shaped openings 49A in the organic insulating layers 49.

The electrode pads 47 are in contact with an under-bump metallization (UBM) layer 57 at each of the sector-shaped openings 49A. That is, the UBM layer 57 is connected to each of the electrode pads 47 at four different (separate) points.

The UBM layer 57 is less in thickness than the stacked layers of the organic insulating layer 49 and the inorganic insulating layer 48, and is formed in steps over the outside and the inside of the sector-shaped openings 49A.

The UBM layer 57 has a three-layer structure of a lower layer formed of the same material as the first UBM layer 50 in the first embodiment, an intermediate layer formed of the same material as the second UBM layer 51 of the first embodiment, and an upper layer formed of the same material as the underlayer 52A (for example, FIG. 5A) of the external connection protruding electrodes 52.

The external connection protruding electrodes 52 are provided on the UBM layer 57. The external connection protruding electrodes 52 are electrically connected to the corresponding electrode pads 47 through the UBM layer 57.

According to this semiconductor device (element) structure, even if cooling after reflow heating at the time of mounting the semiconductor device 150 on the wiring board 71 (FIG. 7) causes a stress to be exerted onto the external connection protruding electrodes 52 of the semiconductor device 150 from the wiring board 71 based on the difference between the coefficients of thermal expansion of the semiconductor device 150 and the wiring board 71, the stress exerted onto the external connection protruding electrodes 52 is divided to be applied to separate regions of the surface of each of the electrode pads 47. That is, the stress is applied to each of the electrode pads 47 in a dispersive manner. This reduces stress concentration in each electrode pad 47.

Accordingly, in this embodiment as well, it is possible to prevent the stress exerted on the external connection protruding electrodes 52 of the semiconductor device 150 from working on the interlayer insulating layers 45 formed of a so-called low-k material in the multi-layer interconnection layer 43 through the electrode pads 47 at the time of mounting the semiconductor device 150 on the wiring board 71. This makes it possible to prevent occurrence of interlayer separation in the interconnection layers 44 stacked alternately with two or more of the interlayer insulating layers 45 and thus to avoid occurrence of electrical failure in the semiconductor device 200 (FIG. 7).

According to the example illustrated in FIGS. 10A and 10B, the exposed surface of each of the electrode pads 47 is divided into four sector-shaped regions. However, this embodiment is not limited to this configuration.

That is, the shape of openings provided in the insulating layer covering the surfaces of the electrode pads 47 may be selected or determined as required. By providing two or more openings, it is possible to distribute the stress exerted on the external connection protruding electrodes 52 of the semiconductor device 150 at the time of mounting the semiconductor device 150 on the wiring board 71.

Semiconductor Device Manufacturing Method According to First Embodiment

A description is given, with reference to FIGS. 5A and 5B, FIG. 7, FIG. 9, and FIG. 11, of a method of manufacturing the semiconductor device 200 according to the first embodiment.

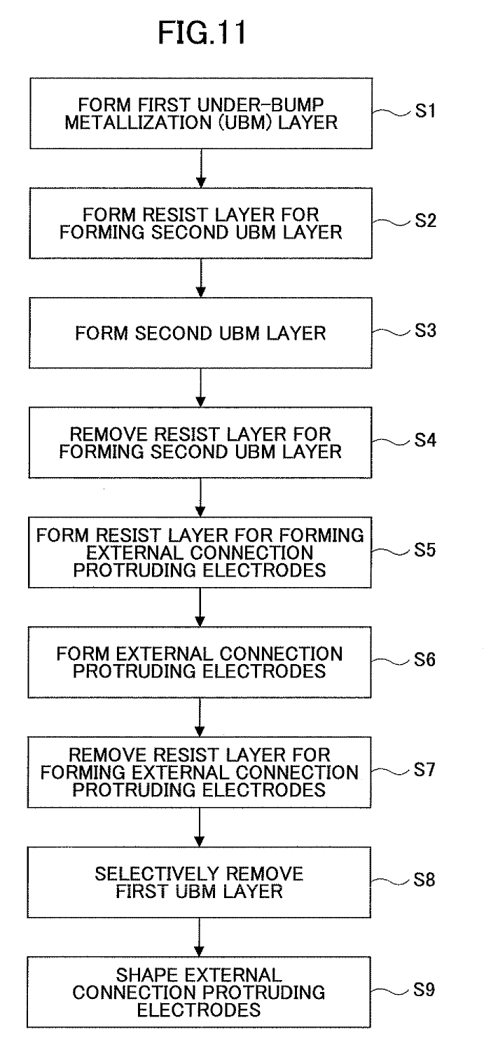

First, in step S1 of FIG. 11, the first UBM layer 50 is deposited by sputtering on the organic insulating layer 49 having openings formed selectively to expose the electrode pads 47 provided over one of the principal surfaces of the semiconductor substrate 41 with interposition of the multi-layer interconnection layer 43. At this point, the openings of the organic insulating layer 40 that expose the electrode pads 47 are set to, for example, 15 μm or more in diameter, and the organic insulating layer 49 is set to, for example, approximately 5 μm or more in film thickness.

Next, in step S2, a photoresist layer is formed on the first UBM layer 50 by spin coating. The photoresist layer is exposed to light, developed, and hardened so as to form openings in the photoresist layer at positions corresponding to where the second UBM layer 51 is to be formed.

The openings are formed at positions offset in the same (uniform) direction from where the electrode pads 47 are formed in the case illustrated in FIGS. 5A and 5B; at positions offset toward the outer edge of the semiconductor device 110 from where the electrode pads 47 are formed in the case illustrated in FIG. 8; and at positions offset toward the center of the semiconductor device 120 from where the electrode pads 47 are formed in the case illustrated in FIG. 9.

Next, in step S3, the second UBM layer 51 is formed in the openings of the photoresist layer by electroplating. At this point, the thickness of the second UBM layer 51 is set to, for example, 5 μm or more.

Next, in step S4, the photoresist layer is removed.

Thereafter, in step S5, another photoresist layer is formed on the layered structures of the first UBM layer 50 and the second UBM layer 51 by spin coating.

Then, the photoresist layer is exposed to light, developed, and hardened so as to form openings in the photoresist layer at positions where the external connection protruding electrodes are to be formed.

Next, in step S6, the underlayer 52A and the low-melting metal layer 52B of the external connection protruding electrodes 52 are successively formed in the openings of the photoresist layer. At this point, part of the low-melting metal layer 52B extends on the photoresist layer.

Thereafter, in step S7, the photoresist layer is removed.

Next, in step S8, unnecessary portions of the first UBM layer 50 are removed by so-called wet etching using the second UBM layer 51 as a mask.

Next, in step S9, the low-melting metal layer 52B is caused to melt by reflow heating so as to be shaped into substantial spheres. As a result, the substantially spherical external connection protruding electrodes 52 are formed on the layered structures of the first UBM layer 50 and the second UBM layer 51 over the semiconductor substrate 41.

After the semiconductor device 100 where the substantially spherical external connection protruding electrodes 52 are thus formed is flip-chip mounted (mounted face-down) on the wiring board 71, the external connection protruding electrodes 52 and additional solder (solder precoat, not graphically illustrated) provided on the electrode pads 72 of the wiring board 71 are caused to melt by reflow heating so as to connect the external connection protruding electrodes 52 of the semiconductor device 100 and the electrode pads 72 on the wiring board 71.

Next, the space between the semiconductor device 100 and the wiring board 71 is filled with the underfill material 74 (FIG. 7), which is then hardened.

Thereafter, solder balls are provided on the lower surface of the wiring board 71, and are subjected to reflow heating and cooling, so that the external connection protruding electrodes 75 are provided on the lower surface of the wiring board 71.

If desirable, a resin sealing part that covers the semiconductor device 100 may be provided before providing the external connection protruding electrodes 75.

As a result, the semiconductor device 200 according to the first embodiment is formed.

Semiconductor Device Manufacturing Method According to Second Embodiment

The semiconductor device (element) 150 illustrated in FIGS. 10A and 10B according to the second embodiment may be formed through the following process.

The inorganic insulating layer 48 and the organic insulating layer 49 are successively deposited and formed by a known method on the multi-layer interconnection layer 43 provided over the semiconductor substrate 41. At this point, openings for selectively exposing the surfaces of the electrode pads 47 are selectively formed in the inorganic insulating layer 48 and the organic insulating layer 49.

That is, selective etching is performed on the inorganic insulating layer 48 covering the electrode pads 47 so as to form openings in the inorganic insulating layer 48, the openings exposing the surfaces of the corresponding electrode pads 47 in multiple regions.

Next, the organic insulating layer 49 is deposited on the inorganic insulating layer 48. Selective etching is performed on the organic insulating layer 49 as well so as to form openings corresponding to the openings provided in the inorganic insulating layer 48 on the electrode pads 47. As a result, the upper surfaces of the electrode pads 47 are exposed in the respective openings provided in the organic insulating layer 49.

Next, the lower layer (a metal layer formed of the same material as the first UBM layer 50 in the first embodiment) of the UBM layer 57 is formed on the exposed portions of the electrode pads 47 and the organic insulating layer 49 by sputtering.

Next, the intermediate layer (a metal layer formed of the same material as the second UBM layer 51 in the first embodiment) of the UBM layer 57 is deposited on the lower layer of the UBM layer 57 by so-called selective plating using a photoresist layer as a mask.

Further, a photoresist layer is applied and formed on the intermediate layer of the UBM layer 57 by spin coating. The photoresist layer is exposed to light, developed, and hardened so as to form openings in the photoresist layer which openings correspond to where the external connection protruding electrodes 52 are to be formed over the electrode pads 47.

Then, the upper layer (a metal layer formed of the same material as the underlayer 52A of the external connection protruding electrodes 52 in the first embodiment) of the UBM layer 57 is formed in the openings of the photoresist layer by electroplating.

Next, the low-melting metal layer (external connection protruding electrode layer) 52B is formed on the upper layer of the UBM layer 57 in the openings of the photoresist layer by electroplating. The low-melting metal layer is formed so that part of the low-melting metal layer extends on the photoresist layer.

Thereafter, the photoresist layer is separated and removed, and unnecessary portions of the UBM layer 57 are removed by so-called wet etching using the external connection protruding electrode layer 52B as a mask.

As a result, in each electrode pad part, the UBM layer 57 is provided in contact with the surface of the electrode pad 47 in the corresponding opening of the organic insulating layer 49 and to extend on the organic insulating layer 49 around the electrode pad 47.

Next, the external connection protruding electrode layer 52B is caused to melt by reflow heating to be shaped into substantial spheres. As a result, the substantially spherical external connection protruding electrodes 52 are formed on the UBM layer 57.

After the semiconductor device 150 where the substantially spherical external connection protruding electrodes 52 are thus formed is flip-chip mounted (mounted face-down) on the wiring board (FIG. 7), the external connection protruding electrodes 52 and additional solder (solder precoat, not graphically illustrated) provided on the electrode pads 72 of the wiring board 71 are caused to melt by reflow heating so as to connect the external connection protruding electrodes 52 of the semiconductor device 150 and the electrode pads 72 on the wiring board 71.

Next, the space between the semiconductor device 150 and the wiring board 71 is filled with the underfill material 74 (FIG. 7), which is then hardened.

Thereafter, solder balls are provided on the lower surface of the wiring board 71, and are subjected to reflow heating and cooling, so that the external connection protruding electrodes 75 are provided on the lower surface of the wiring board 71. If desirable, a resin sealing part that covers the semiconductor device 150 may be provided before providing the external connection protruding electrodes 75.

As a result, a semiconductor device according to the second embodiment is formed.

According to an aspect of the present invention, one or more of the above-described features may be applied to semiconductor devices including those to be mounted on a wiring board through external connection protruding electrodes.

All examples and conditional language recited herein are intended for pedagogical purposes to aid the reader in understanding the invention and the concepts contributed by the inventors to furthering the art, and are to be construed as being without limitation to such specifically recited examples and conditions, nor does the organization of such examples in the specification relate to a showing of the superiority or inferiority of the invention. Although the embodiments of the present inventions have been described in detail, it should be understood that various changes, substitutions, and alterations could be made hereto without departing from the spirit and scope of the invention.

What is claimed is:

1. A semiconductor device, comprising:
a plurality of electrode pads provided in an interconnection layer over a semiconductor substrate;
an insulating layer provided on the interconnection layer so as to expose portions of the electrode pads;
a plurality of conductive layers having
respective first ends thereof connected to the exposed portions of the corresponding electrode pads so as to extend therefrom on the insulating layer; and
a plurality of protruding electrodes provided at respective second ends of the conductive layers,
wherein the conductive layers extend in a given direction relative to the electrode pads.

2. The semiconductor device as claimed in claim 1, wherein the electrode pads are provided at substantially equal intervals vertically and horizontally in a matrix on a principal surface of the semiconductor substrate.

3. The semiconductor device as claimed in claim 2, wherein the protruding electrodes are provided at substantially equal intervals vertically and horizontally in a matrix on a principal surface of the semiconductor substrate.

4. The semiconductor device as claimed in claim 1, wherein distances between the electrode pads and the corresponding protruding electrodes connected to the electrode pads through the conductive layers are equal.

5. The semiconductor device as claimed in claim 1, wherein the conductive layers extend in a uniform direction.

6. The semiconductor device as claimed in claim 1, wherein the conductive layers extend in a direction from a center of the semiconductor substrate toward a periphery thereof.

7. The semiconductor device as claimed in claim 1, wherein the conductive layers extend in a direction from a periphery of the semiconductor substrate toward a center thereof.

8. The semiconductor device as claimed in claim 1, wherein the insulating layer comprises:
an inorganic insulating film; and
an organic insulating film formed on the inorganic insulating film.

9. The semiconductor device as claimed in claim 8, wherein the inorganic insulating film has openings on the electrode pads, the openings being greater than or equal to 15 μm in diameter.

10. The semiconductor device as claimed in claim 9, wherein the organic insulating film has openings formed in the openings of the inorganic insulating film.

11. The semiconductor device as claimed in claim 8, wherein the organic insulating film is more than or equal to 5 μm in thickness.

12. The semiconductor device as claimed in claim 1, wherein the conductive layers comprise a plurality of metal layers.

13. The semiconductor device as claimed in claim 12, wherein the conductive layers comprise:
a first under-bump metallization layer formed of a material including one of titanium and chromium; and
a second under-bump metallization layer formed of a material including one of copper and nickel.

14. The semiconductor device as claimed in claim 1, wherein the interconnection layer comprises an interlayer insulating film having a relative dielectric constant lower than or equal to 5.

15. The semiconductor device as claimed in claim 1, wherein the protruding electrodes have one of a substantially hemispherical shape and a substantially cylindrical shape.
